(19) United States
(12) Patent Application Publication
(10) Pub. No.: US 2025/0360542 A1
(43) Pub. Date: Nov. 27, 2025

(54) PROCESSING LIQUID SUPPLY DEVICE AND PROCESSING LIQUID SUPPLY METHOD

(71) Applicant: SCREEN HOLDINGS CO., LTD., Kyoto (JP)

(72) Inventors: Tomoaki AIHARA, Kyoto-shi (JP); Hirofumi NAGATA, Kyoto-shi (JP); Shinji TAHARA, Kyoto-shi (JP)

(21) Appl. No.: 19/217,312

(22) Filed: May 23, 2025

(30) Foreign Application Priority Data
May 27, 2024 (JP) 2024-085275

(51) Int. Cl. B08B 3/10; H01L 21/67

(52) U.S. Cl. CPC B08B 3/10; H01L 21/67017

(57) ABSTRACT

A supply pipe connects an inlet of a storage to a substrate processing apparatus. A circulation pipe connects the substrate processing apparatus to an inlet of the storage. A pump sends out a processing liquid stored in the storage from an outlet to a supply pipe. A liquid drain is provided in the circulation pipe and is configured to be capable of discharging the processing liquid flowing through the circulation pipe. A replenisher is configured to be capable of replenishing the storage with the processing liquid. In a case in which a temperature setting value is changed, a control device brings a temperature of the processing liquid close to a changed setting value by controlling the liquid drain and the replenisher based on a temperature of the processing liquid in the entire circulation path that includes a temperature of the processing liquid flowing through the circulation path.

### BACKGROUND

### Technical Field

The present disclosure relates to a processing liquid supply device and a processing liquid supply method for supplying a processing liquid.

### Description of Related Art

A substrate processing apparatus is used to execute various processes on a substrate such as a semiconductor substrate, a substrate for an FPD (Flat Panel Display) such as a liquid crystal display device, an organic EL (Electro Luminescence) display device or the like, a substrate for an optical disc, a substrate for a magnetic disc, a substrate for a magneto-optical disc, a substrate for a photomask, a ceramic substrate or a substrate for a solar cell. A processing liquid supply device regulates a processing liquid used for a liquid process for a substrate to any temperature and supplies the processing liquid having a regulated temperature to a substrate processing apparatus. In recent years, in order to reduce energy consumption and processing liquid consumption, a circulation-type processing liquid supply device to which a processing liquid that has been supplied to a substrate processing apparatus is returned has been used.

For example, in a pure water heating device described in JP 2018-119756 A, pure water stored in a tank is supplied to a substrate processing apparatus through a pipe provided with a heater. The pure water that has been supplied to the substrate processing apparatus circulates back to the tank through a return pipe. A fluid supply valve that supplies pure water before being heated and a fluid discharge valve that discharges heated pure water are connected to the tank. Further, in each component of the pure water heating device, a temperature sensor for detecting a temperature of pure water is provided. The operations of the fluid supply valve, the fluid discharge valve and the heater are controlled such that a detection value of the temperature sensor is a setting temperature.

### SUMMARY

The processing liquid supply device may be provided to be relatively spaced apart from the substrate processing apparatus. In this case, since a pipe connecting the substrate processing apparatus to the pure water heating device is long and the volume of the pipe is large, the volume of pure water flowing through the pipe cannot be ignored. Therefore, in the pure water heating device described in JP 2018-119756 A, in a case in which the processing liquid supply device and the substrate processing apparatus are relatively spaced apart from each other, because a temperature of pure water in the pipe connecting the substrate processing apparatus to the pure water heating device is not detected, it is difficult to supply pure water having an appropriately regulated temperature to the substrate processing apparatus.

An object of the present disclosure is to provide a processing liquid supply device capable of supplying a processing liquid having an appropriately regulated temperature to a substrate processing apparatus, and a processing liquid supply method with which the processing liquid having the appropriately regulated temperature can be supplied to the substrate processing apparatus.

A processing liquid supply device according to one aspect of the present disclosure that supplies a processing liquid to a substrate processing apparatus, includes a storage that stores the processing liquid and has an outlet through which the stored processing liquid is sent and an inlet through which the processing is fed, a supply pipe that connects the outlet of the storage to the substrate processing apparatus, a circulation pipe that connects the substrate processing apparatus to the inlet of the storage, a pump that sends out the processing liquid stored in the storage from the outlet to the supply pipe, a liquid drain that is provided in the circulation pipe and configured to be capable of discharging the processing liquid flowing through the circulation pipe, a replenisher configured to be capable of replenishing the storage with the processing liquid, and a controller that, in a case in which a temperature setting value is changed, brings a temperature of the processing liquid close to a changed setting value by controlling the liquid drain and the replenisher based on a temperature of the processing liquid in an entire circulation path that includes a temperature of the processing liquid flowing through the circulation pipe.

A processing liquid supply method according to another aspect of the present disclosure of supplying a processing liquid having a setting temperature to a substrate processing apparatus using a processing liquid supply device, includes sending out the processing liquid stored in a storage using a pump to a supply pipe that connects an outlet of the storage to the substrate processing apparatus, feeding the processing liquid into the storage using a circulation pipe that connects the substrate processing apparatus to an inlet of the storage, and in a case in which a temperature setting value is changed, based on a temperature of the processing liquid in an entire circulation path that includes a temperature of the processing liquid flowing through the circulation pipe, bringing the temperature of the processing liquid close to a changed setting value by discharging the processing liquid flowing through the circulation pipe using a liquid drain provided in the circulation pipe and replenishing the storage with the processing liquid.

With the present disclosure, it is possible to supply the processing liquid having an appropriately regulated temperature to the substrate processing apparatus.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a diagram showing the configuration of a substrate processing system including a processing liquid supply device according to a first embodiment of the present disclosure;

FIG. 2 is a diagram showing the configuration of a control device of FIG. 1;

FIG. 3 is a flowchart showing the algorithm of a processing liquid supply process executed by a processing liquid supply program;

FIG. 4 is a flowchart showing the algorithm of a processing liquid supply process in a second embodiment;

FIG. 5 is a diagram showing the configuration of a control device in a third embodiment;

FIG. 6 is a flowchart showing the algorithm of a processing liquid supply process in the third embodiment; and

FIG. 7 is a flowchart showing the algorithm of the processing liquid supply process in the third embodiment.

### DETAILED DESCRIPTION

A processing liquid supply device and a processing liquid supply method according to one embodiment of the present disclosure will be described below with reference to the drawings. In the following description, a substrate refers to a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate, a substrate for a solar cell or the like.

### 1. First Embodiment

### (1) Configuration of Substrate Processing System

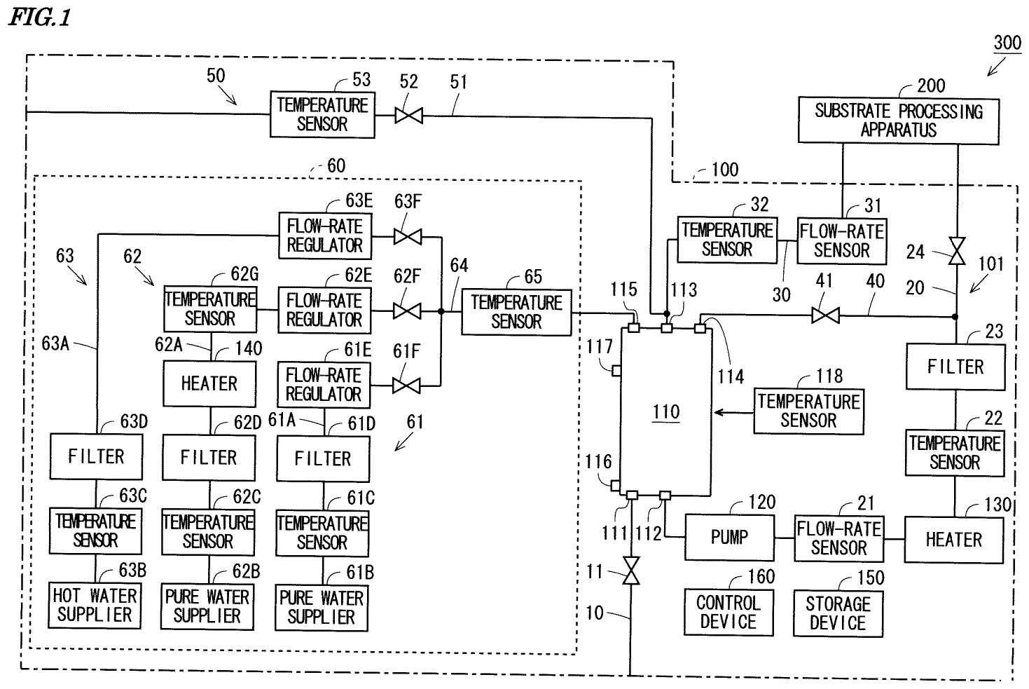

FIG. 1 is a diagram showing the configuration of a substrate processing system including a processing liquid supply device according to a first embodiment of the present disclosure. As shown in FIG. 1, the substrate processing system 300 includes a processing liquid supply device 100 and a substrate processing apparatus 200, and is installed in a factory, for example. The processing liquid supply device 100 supplies a processing liquid having a setting temperature to the substrate processing apparatus 200. While the processing liquid is pure water in the present example, the embodiment is not limited to this. The processing liquid may be another liquid such as a chemical liquid. The substrate processing apparatus 200 executes a process such as cleaning on a substrate using the processing liquid supplied by the processing liquid supply device 100.

The processing liquid supply device 100 includes a storage 110, a pump 120, heaters 130, 140, a memory device 150 and a control device 160, and also includes various elements such as a temperature sensor, a flow-rate sensor, a filter and an open-close valve. Further, the processing liquid supply device 100 includes a plurality of pipes such as a liquid drain pipe 10, a supply pipe 20, a circulation pipe 30 and a branch pipe 40. In the following description, the direction in which the processing liquid flows in each pipe is defined as a downstream direction, and the direction opposite to the downstream direction is defined as an upstream direction.

The storage 110 is a tank, for example, and stores the processing liquid. The storage 110 includes outlets 111, 112 and inlets 113, 114, 115. The processing liquid stored in the storage 110 is sent out from each of the outlets 111, 112. The processing liquid is fed into the storage 110 from each of the inlets 113 to 115. The processing liquid send out from the outlet 112 is mainly fed from the inlet 113 or the inlet 114 into the storage 110. The processing liquid supplied from a replenisher 60, described below, is fed from the inlet 115 into the storage 110.

In the storage 110, liquid level sensors 116, 117 and a temperature sensor 118 are provided. The liquid level sensor 116 is arranged in a lower portion of the storage 110, and detects a liquid level of the processing liquid when an amount of the processing liquid stored in the storage 110 is a predetermined lower limit amount. The liquid level sensor 117 is arranged above the liquid level sensor 116, and detects a liquid level of the processing liquid when an amount of the processing liquid stored in the storage 110 is a predetermined upper limit amount. The temperature sensor 118 detects a temperature of the processing liquid stored in the storage 110. Detection results of the liquid level sensors 116, 117 and the temperature sensor 118 are provided to the control device 160.

The liquid drain pipe 10 connects the outlet 111 of the storage 110 to a liquid drain device (not shown) provided as a factory facility. An open-close valve 11 is provided in the liquid drain pipe 10. The open-close valve 11 is switched between an open state and a close state by the control device 160. When the open-close valve 11 is in the open state, the processing liquid stored in the storage 110 is sent out through the outlet 111 and is discharged to the liquid drain device through the liquid drain pipe 10.

The supply pipe 20 connects the outlet 112 of the storage 110 to the substrate processing apparatus 200. In the supply pipe 20, the pump 120 and the heater 130 are provided, and a flow-rate sensor 21, a temperature sensor 22, a filter 23 and an open-close valve 24 are provided. While the pump 120, the flow-rate sensor 21, the heater 130, the temperature sensor 22, the filter 23 and the open-close valve 24 are arranged in this order from an upstream position to a downstream position in the present example, the order in which the pump 120, the heater 130, the flow-rate sensor 21, the temperature sensor 22 and the filter 23 are arranged is not limited. The pump 120 sends out the processing liquid stored in the storage 110 to the supply pipe 20 from the outlet 112. The 5 heater 130 heats the processing liquid flowing through the supply pipe 20.

The flow-rate sensor 21 detects a flow rate of the processing liquid flowing through the supply pipe 20. The temperature sensor 22 detects a temperature of the processing liquid flowing through the supply pipe 20. Detection results of the flow-rate sensor 21 and the temperature sensor 22 are provided to the control device 160. The filter 23 removes foreign matter from the processing liquid flowing through the supply pipe 20. The open-close valve 24 is switched between an open state and a close state by the control device 160. When the open-close valve 24 is in the open state, the processing liquid stored in the storage 110 is sent out through the outlet 112 and is supplied to the substrate processing apparatus 200 through the supply pipe 20.

The circulation pipe 30 connects the substrate processing apparatus 200 to the inlet 113 of the storage 110. In the circulation pipe 30, a flow-rate sensor 31 and a temperature sensor 32 are provided. While the flow-rate sensor 31 and the temperature sensor 32 are arranged in this order from an upstream position to a downstream position in the present example, the order in which the flow-rate sensor 31 and the temperature sensor 32 are arranged is not limited. The flow-rate sensor 31 detects a flow rate of the processing liquid flowing through the circulation pipe 30. The temperature sensor 32 detects a temperature of the processing liquid flowing through the circulation pipe 30. Detection results of the flow-rate sensor 31 and the temperature sensor 32 are provided to the control device 160. The processing liquid which is not used in the substrate processing apparatus 200 is fed into the storage 110 through the circulation pipe 30 and the inlet 113.

With the above-mentioned connection, the storage 110, the supply pipe 20 and the circulation pipe 30 form a circulation path 101 for causing the processing liquid to circulate through the substrate processing apparatus 200. In the present embodiment, the processing liquid supply device 100 and the substrate processing apparatus 200 are provided to be relatively apart from each other. Therefore, the supply pipe 20 and the circulation pipe 30 are relatively long. Further, in order to reduce a loss of pressure, the cross-sectional areas of the supply pipe 20 and the circulation pipe 30 are relatively large.

Therefore, the volume of each of the supply pipe 20 and the circulation pipe 30 is unneligibly large compared to the volume of the storage 110. In the present example, the sum of the volume of the supply pipe 20 and the volume of the circulation pipe 30 is larger than the volume of the storage 110.

The branch pipe 40 connects a portion of the supply pipe 20 upstream of the open-close valve 24 in the supply pipe 20 to the inlet 114 of the storage 110. An open-close valve 41 is provided in the branch pipe 40. The open-close valve 41 is switched between an open state and a close state by the control device 160. When the open-close valve 41 is in the open state, the processing liquid flowing through the supply pipe 20 is fed into the storage 110 through the branch pipe 40 and the inlet 114. In this manner, by using the branch pipe 40 that branches from the supply pipe 20, it is possible to cause the processing liquid to circulate without flowing through the substrate processing apparatus 200.

The processing liquid supply device 100 further includes a liquid drain 50 and the replenisher 60. The liquid drain 50 is configured to be capable of discharging the processing liquid flowing through the circulation pipe 30, and includes a liquid drain pipe 51, an open-close valve 52 and a temperature sensor 53. The liquid drain pipe 51 connects the circulation pipe 30 to a liquid drain device (not shown). In the present example, the upstream end portion of the liquid drain pipe 51 is connected to the vicinity of the downstream end portion of the circulation pipe 30 (a portion located farther upstream than the downstream end portion of the circulation pipe 30 by a predetermined length, for example). That is, the liquid drain pipe 51 is provided so as to branch from the vicinity of the downstream end portion of the circulation pipe 30.

The open-close valve 52 and the temperature sensor 53 are provided in the liquid drain pipe 51. While the open-close valve 52 and the temperature sensor 53 are arranged in this order from an upstream position toward a downstream position in the present example, the order in which the open-close valve 52 and the temperature sensor 53 are arranged is not limited. The open-close valve 52 is switched between an open state and a close state by the control device 160. When the open-close valve 52 is in the open state, the processing liquid flowing through the circulation pipe 30 is drained to the liquid drain device through the liquid drain pipe 51. The temperature sensor 53 detects a temperature of the processing liquid flowing through the liquid drain pipe 51. A detection result of the temperature sensor 53 is provided to the control device 160.

The replenisher 60 is configured to be capable of replenishing the storage 110 with the processing liquid, and includes replenishment units 61, 62, 63, a replenishment pipe 64 and a temperature sensor 65. The replenishment unit 61 includes a replenishment pipe 61A, a pure water supplier 61B, a temperature sensor 61C, a filter 61D, a flow-rate regulator 61E and an open-close valve 61F. The upstream end portion of the replenishment pipe 61A is connected to the pure water supplier 61B. The pure water supplier 61B supplies pure water as a processing liquid.

The temperature sensor 61C, the filter 61D, the flow-rate regulator 61E and the open-close valve 61F are provided in the replenishment pipe 61A. While the temperature sensor 61C, the filter 61D, the flow-rate regulator 61E and the open-close valve 61F are arranged in this order from an upstream position toward a downstream position in the present example, the order in which the temperature sensor 61C, the filter 61D, the flow-rate regulator 61E and the open-close valve 61F are arranged is not limited.

The temperature sensor 61C detects a temperature of the processing liquid flowing through the replenishment pipe 61A. The filter 61D removes foreign matter from the processing liquid flowing through the replenishment pipe 61A. The flow-rate regulator 61E detects a flow rate of the processing liquid flowing through the replenishment pipe 61A and regulates a flow rate of the processing liquid flowing through the replenishment pipe 61A. The open-close valve 61F is switched between an open state and a close state by the control device 160. When the open-close valve 61F is in the open state, the processing liquid supplied by the pure water supplier 61B is sent downstream through the pure water supplier 61B.

The replenishment unit 62 includes a replenishment pipe 62A, a pure water supplier 62B, a temperature sensor 62C, a filter 62D, a flow-rate regulator 62E, an open-close valve 62F and a temperature sensor 62G. The upstream end portion of the replenishment pipe 62A is connected to the pure water supplier 62B. The pure water supplier 62B supplies pure water as a processing liquid.

The temperature sensor 62C, the filter 62D, the flow-rate regulator 62E, the open-close valve 62F and the temperature sensor 62G are provided in the replenishment pipe 62A. Further, the heater 140 is provided in the replenishment pipe 62A. In the present example, the temperature sensor 62C, the filter 62D, the heater 140, the temperature sensor 62G, the flow-rate regulator 62E and the open-close valve 62F are arranged in this order from an upstream position to a downstream position. However, as long as the temperature sensor 62C is located farther upstream than the heater 140 and the temperature sensor 62G is located farther downstream than the heater 140, the order in which the temperature sensor 62C, the filter 62D, the heater 140, the temperature sensor 62G, the flow-rate regulator 62E and the open-close valve 62F are arranged is not limited.

The heater 140 heats the processing liquid flowing through the replenishment pipe 62A. The temperature sensors 62C, 62G detect temperatures of the processing liquid flowing through the replenishment pipe 62A. The filter 62D removes foreign matter from the processing liquid flowing through the replenishment pipe 62A. The flow-rate regulator 62E detects a flow rate of the processing liquid flowing through the replenishment pipe 62A and regulates a flow rate of the processing liquid flowing through the replenishment pipe 62A. The open-close valve 62F is switched between an open state and a close state by the control device 160. When the open-close valve 62F is in the open state, the processing liquid supplied by the pure water supplier 62B is sent downstream through the pure water supplier 62B.

The replenishment unit 63 includes a replenishment pipe 63A, a hot water supplier 63B, a temperature sensor 63C, a filter 63D, a flow-rate regulator 63E and an open-close valve 63F. The upstream end portion of the replenishment pipe 63A is connected to the hot water supplier 63B. The hot water supplier 63B supplies hot water as a processing liquid. The hot water is heated pure water that is supplied as a use force from a factory where the substrate processing system 300 is installed. Since the temperature of the hot water is regulated in advance in another facility of the substrate processing system 300 of the factory in which the substrate processing system 300 is installed, the hot water has a relatively high temperature.

The temperature sensor 63C, the filter 63D, the flow-rate regulator 63E and the open-close valve 63F are provided in the replenishment pipe 63A. While the temperature sensor 63C, the filter 63D, the flow-rate regulator 63E and the open-close valve 63F are arranged in this order from an upstream position toward a downstream position in the present example, the order in which the temperature sensor 63C, the filter 63D, the flow-rate regulator 63E and the open-close valve 63F are arranged is not limited.

The temperature sensor 63C detects a temperature of the processing liquid flowing through the replenishment pipe 63A. The filter 63D removes foreign matter from the processing liquid flowing through the replenishment pipe 63A. The flow-rate regulator 63E detects a flow rate of the processing liquid flowing through the replenishment pipe 63A and regulates the flow rate of the processing liquid flowing through the replenishment pipe 63A. The open-close valve 63F is switched between an open state and a close state by the control device 160. When the open-close valve 63F is in the open state, the processing liquid supplied by the hot water supplier 63B is sent downstream through the hot water supplier 63B.

Downstream end portions of the replenishment pipes 61A to 63A are joined and connected to the upstream end portion of the replenishment pipe 64. The downstream end portion of the replenishment pipe 64 is connected to the inlet 115 of the storage 110. With this connection, the processing liquid sent out by any one of the replenishment units 61 to 63 is fed into the storage 110 through the replenishment pipe 64 and the inlet 115. Thus, the storage 110 is replenished with the processing liquid.

The temperature sensor 65 is provided in the replenishment pipe 64. The temperature sensor 65 detects a temperature of the processing liquid flowing through the replenishment pipe 64. The detection results of the temperature sensors 61C to 63C, 62G, 65 and the flow-rate regulators 61E to 63E in the replenisher 60 are provided to the control device 160. Each of the flow-rate regulators 61E to 63E may include a flow-rate switch and a motor needle valve, for example.

The memory device 150 stores a processing liquid supply program for causing the control device 160 to execute a processing liquid supply process. Further, the memory device 150 stores the volume of the entire circulation path 101. The volume of the entire circulation path 101 may include the volume of the pump 120, the heater 130, the flow-rate sensor 21, the temperature sensor 22, the filter 23 or the open-close valve 24. Further, the volume of the entire circulation path 101 may include the volume of the flow-rate sensor 31 or the temperature sensor 32. Further, the volume of the entire circulation path 101 may include the volume of the branch pipe 40. In this case, the volume of the entire circulation path 101 may further include the volume of the open-close valve 41.

Based on the detection results provided from various sensors, the control device 160 executes the processing liquid supply process by controlling various constituent elements of the substrate processing apparatus 200. The processing liquid supply process includes a temperature change process, a liquid supply process, a temperature regulating process and a liquid drain process. The temperature change process is a process of, in a case in which a temperature setting value is changed, bringing a temperature of the processing liquid close to a changed setting value by controlling the liquid drain 50 and the replenisher 60 based on a temperature of the processing liquid in the entire circulation path 101 which includes a temperature of the processing liquid flowing through the circulation pipe 30. Details of the temperature change process will be described below in detail, and the details about the rest of the processing liquid supply process will not be described.

The liquid supply process is a process of supplying the processing liquid having an amount in a predetermined range into the storage 110 by controlling the replenisher 60 based on detection results of the liquid level sensors 116, 117. The temperature regulating process is a process of supplying the processing liquid to the substrate processing apparatus 200 while maintaining the processing liquid at a setting temperature by controlling the pump 120 and the heater 130 and opening the open-close valve 24. When the processing liquid is not supplied to the substrate processing apparatus 200, the open-close valve 41 may be opened instead of the open-close valve 24. The liquid drain process is a process of discharging the processing liquid from the circulation path 101 by controlling the pump 120 and opening the open-close valves 11, 24, 52, and is executed in a case in which the processing liquid is contaminated, etc.

### (2) Processing Liquid Supply Process

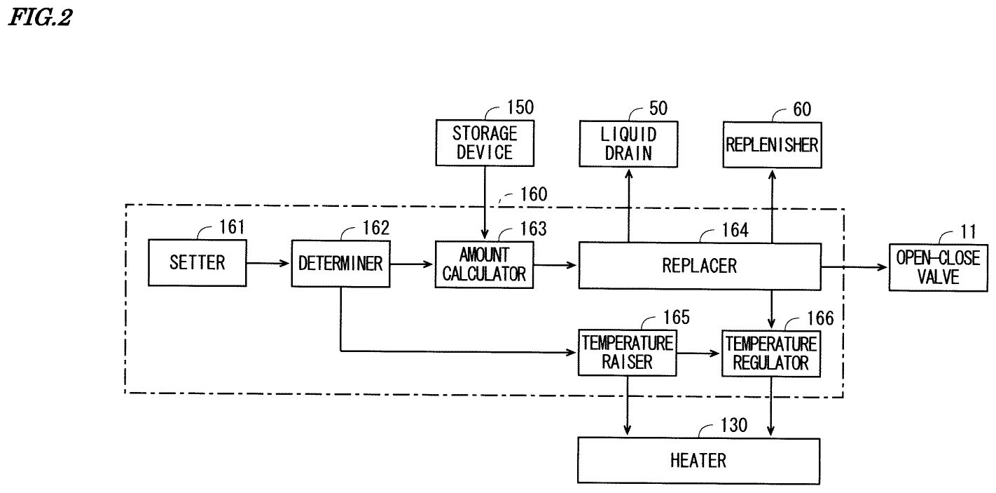

FIG. 2 is a diagram showing the configuration of the control device 160 of FIG. 1. As shown in FIG. 2, the control device 160 includes a setter 161, a determiner 162, an amount calculator 163, a replacer 164, a temperature raiser 165 and a temperature regulator 166 as functions. The functions of the control device 160 are implemented by execution of the processing liquid supply program stored in the memory device 150 by the control device 160. Part or all of the functions of the control device 160 may be implemented by hardware such as an electronic circuit. Further, the processing liquid supply program may be stored in a memory medium different from the memory device 150.

The setter 161 sets a temperature of the processing liquid based on a designation made by a user. Specifically, the setter 161 sets a temperature setting value of the processing liquid to a setting value designated by the user. Therefore, in a case in which a setting value is changed by the user, the setter 161 sets a temperature setting value of the processing liquid to a changed setting value.

The determiner 162 specifies a temperature of the processing liquid in the entire circulation path 101 based on temperatures detected by the temperature sensors 22, 32, 118. The temperature of the processing liquid in the entire circulation path 101 may be specified as a calculation value of the temperatures detected by the temperature sensors 22, 32, 118. The calculation value may be an average value (including a weighted average value), or may be another calculation value. Further, in a case in which a temperature setting value of the processing liquid is changed by the setter 161, the determiner 162 determines whether a changed setting value is lower than the specified temperature of the processing liquid in the entire circulation path 101.

The amount calculator 163 calculates a replacement amount of the processing liquid for making a temperature of the processing liquid reach a changed setting value based on the volume of the entire circulation path 101 stored in the memory device 150 and a temperature of the processing liquid in the entire circulation path 101 specified by the determiner 162. Even in a case in which a temperature of the processing liquid is lower than a setting value, it is relatively easy to raise the temperature of the processing liquid to the setting value. As such, in the present example, as a replacement amount for making a temperature of the processing liquid reach a changed setting value, the amount calculator 163 calculates a replacement amount of the processing liquid that makes the temperature of the processing liquid reach a temperature slightly lower than the changed setting value (hereinafter referred to as a target temperature).

The replacer 164 replaces the processing liquid having a replacement amount calculated by the amount calculator 163 by executing a discharge process of discharging the processing liquid using the liquid drain 50 and a replenishment process of replenishing the storage 110 with the processing liquid by using the replenisher 60. In the present embodiment, in a case in which a changed temperature setting value is lower than a temperature of the processing liquid in the entire circulation path 101, the replacer 164 sequentially executes the discharge process of discharging the processing liquid having a replacement amount and the replenishment process of replenishing the storage 110 with the processing liquid having the replacement amount. Further, the replacer 164 may further open the open-close valve 11 in the discharge process. Further, in a case in which the processing liquid having an amount in the predetermined range is not stored in the storage 110, the replacer 164 may replenish the storage 110 with the processing liquid by controlling the replenisher 60.

In a case in which a changed temperature setting value is higher than a temperature of the processing liquid in the entire circulation path 101, the temperature raiser 165 executes a first temperature raising process. The first temperature raising process is a process of controlling the heater 130 to bring a temperature of the processing liquid close to a changed setting value without replacement of the processing liquid by the replacer 164. Specifically, the processing liquid flowing through the supply pipe 20 is heated by execution of the first temperature raising process until the temperature of the processing liquid reaches a target temperature.

In a case in which the replacer 164 executes the discharge process and the replenishment process, or a case in which the temperature raiser 165 executes the first temperature raising process, the temperature of the processing liquid reaches a target temperature. That is, the temperature of the processing liquid is slightly lower than a setting value. As such, the temperature regulator 166 heats the processing liquid flowing through the supply pipe 20 using the heater 130 such that the temperature of the processing liquid is slightly raised. Thus, the temperature of the processing liquid is finely regulated to the setting value.

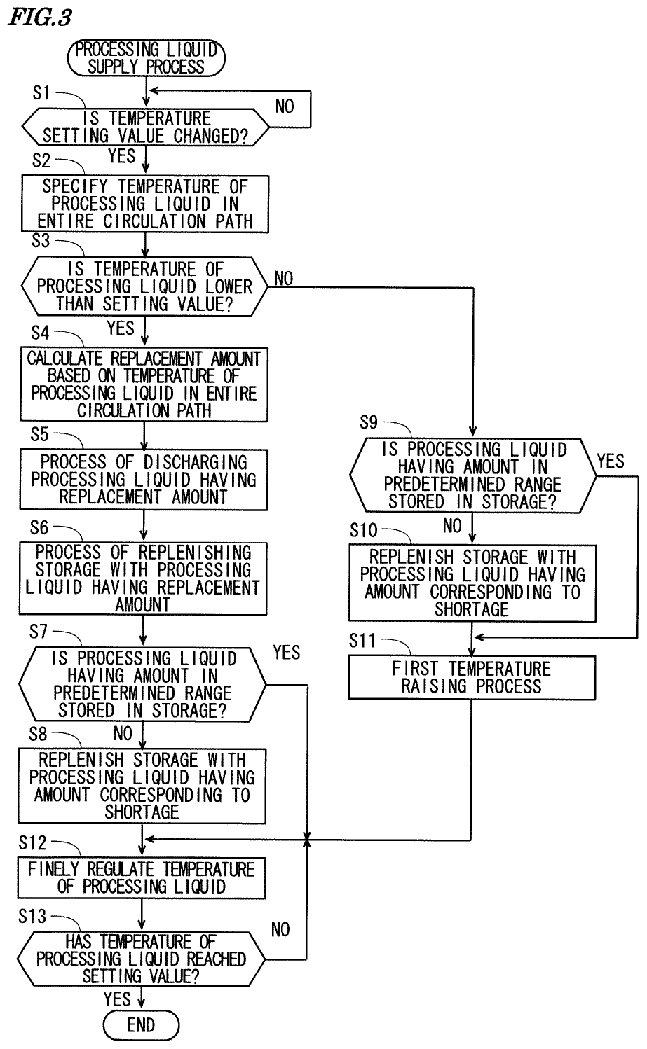

FIG. 3 is a flowchart showing the algorithm of the processing liquid supply process executed by the processing liquid supply program. The processing liquid supply process will be described below with reference to the processing liquid supply device 100 of FIG. 1, the control device 160 of FIG. 2 and the flowchart of FIG. 3. As described above, the processing liquid supply process of FIG. 3 is the temperature change process. In the temperature change process, as an initial state, the processing liquid having an amount in the predetermined range is stored in the storage 110, the open-close valve 24 is opened, and the processing liquid circulates the circulation path 101 due to an operation of the pump 120. Further, the open-close valves other than the open-close valve 24 are closed.

First, the setter 161 determines whether a temperature setting value of the processing liquid is changed (step S1). In a case in which the temperature setting value is not changed, the setter 161 waits until the temperature setting value of the processing liquid is changed. In a case in which the temperature setting value is changed, the determiner 162 specifies a temperature of the processing liquid in the entire circulation path 101 (step S2). The step S2 is executed based on the temperatures detected by the temperature sensors 22, 32, 118.

Next, the determiner 162 determines whether the temperature setting value that is changed in the step S1 is lower than the temperature of the processing liquid in the entire circulation path 101 specified in the step S2 (step S3). In a case in which it is determined that the temperature setting value is lower than the temperature of the processing liquid in the entire circulation path 101, the amount calculator 163 calculates a replacement amount of the processing liquid for making the temperature of the processing liquid in the entire circulation path 101 reach a target temperature, based on the volume of the entire circulation path 101, an amount of the processing liquid in the storage 110 based on the detection results of the liquid level sensors 116, 117, and the temperature of the processing liquid in the entire circulation path 101 specified in the step S2 (step S4). The target temperature is a temperature slightly lower than the changed temperature setting value.

Subsequently, the replacer 164 executes the discharge process of discharging the processing liquid having the replacement amount calculated in the step S4 from the circulation path 101 by opening the open-close valve 52 of the liquid drain 50 (step S5). In the present example, the replacer 164 further opens the open-close valve 11 in the discharge process. The amount of the processing liquid to be discharged from the circulation path 101 is managed based on the detection results of the flow-rate sensors 21, 31 and the liquid level sensors 116, 117. After the process of discharging the processing liquid having the replacement amount ends, the replacer 164 closes the open-close valves 11,52.

Thereafter, the replacer 164 executes the replenishment process of replenishing the storage 110 with the processing liquid having the replacement amount calculated in the step S4 by opening the open-close valve 61F of the replenisher 60 (step S6). The amount of the processing liquid with which the storage 110 is replenished is managed based on the detection results of the flow-rate regulator 61E and the liquid level sensors 116, 117. After the process of replenishing the storage 110 with the processing liquid having the replacement amount ends, the replacer 164 closes the open-close valve 61F. At this time, the determiner 162 may confirm, based on temperatures detected by the temperature sensors 22, 32, 118, that the temperature of the processing liquid in the entire circulation path 101 reaches the target temperature.

Next, the replacer 164 determines, based on the detection results of the liquid level sensors 116, 117, whether the processing liquid having an amount in the predetermined range is stored in the storage 110 (step S7). In a case in which it is determined that the processing liquid having an amount in the predetermined range is not stored in the storage 110, the replacer 164 replenishes the storage 110 with the processing liquid having an amount corresponding to the shortage by opening the open-close valve 61F (step S8). In a case in which the target temperature is relatively high, the open-close valve 62F or the open-close valve 63F may be opened instead of the open-close valve 61F. After the storage 110 is replenished with the processing liquid having an amount corresponding to the shortage, the open-close valves 61F to 63F are closed. At this time, based on the detection results of the flow-rate sensors 21, 31 and the liquid level sensors 116, 117, the replacer 164 may confirm that the circulation path 101 is filled with the processing liquid.

Even in a case in which it is determined in the step S3 that the temperature setting value is higher than the temperature of the processing liquid in the entire circulation path 101, the replacer 164 determines whether the processing liquid having an amount in the predetermined range is stored in the storage 110 similarly to the step S7 (step S9). In a case in which it is determined that the processing liquid having an amount in the predetermined range is not stored in the storage 110, the replacer 164 replenishes the storage 110 with the processing liquid having an amount corresponding to the shortage by opening part or all of the open-close valves 61F to 63F similarly to the step S8 (step S10). After the storage 110 is replenished with the processing liquid having an amount corresponding to the shortage, the open-close valves 61F to 63F are closed. At this time, based on the detection results of the flow-rate sensors 21, 31 and the liquid level sensors 116, 117, the replacer 164 may confirm that the circulation path 101 is filled with the processing liquid.

In a case in which it is determined in the step S9 that the processing liquid having an amount in the predetermined range is stored in the storage 110, or a case in which the storage 110 is replenished with the processing liquid having an amount corresponding to the shortage in the step S10, the process proceeds to the step S11. In the step S11, the temperature raiser 165 executes the first temperature raising process (step S11). In the present embodiment, the first temperature raising process is a process of bringing the temperature of the processing liquid in the entire circulation path 101 close to the changed setting value, and is executed by control of the heater 130.

In a case in which it is determined in the step S7 that the processing liquid having an amount in the predetermined range is stored in the storage 110, a case in which the storage 110 is replenished with the processing liquid having an amount corresponding to the shortage in the step S8, or a case in which the first temperature raising process is executed in the step S11, the process proceeds to the step S12. In the step S12, the temperature regulator 166 finely regulates the temperature of the processing liquid by heating the processing liquid flowing through the supply pipe 20 using the heater 130 (step S12).

Thereafter, the temperature regulator 166 determines whether the temperature of the processing liquid in the entire circulation path 101 specified by the determiner 162 has reached the setting value (step S13). In a case in which it is determined that the temperature of the processing liquid in the entire circulation path 101 has not reached the setting value, the process returns to the step S12. The steps S12 and S13 are repeated until it is determined that the temperature of the processing liquid in the entire circulation path 101 has reached the setting value. In a case in which it is determined in the step S13 that the temperature of the processing liquid in the entire circulation path 101 has reached the setting value, the processing liquid supply process ends.

### (3) Effects

In the processing liquid supply device 100 according to the present embodiment, the liquid drain 50 and the replenisher 60 operate based on a temperature of the processing liquid in the entire circulation path 101 including a temperature of the processing liquid flowing through the circulation pipe 30. Therefore, even in a case in which the volume of the circulation pipe 30 is large since the processing liquid supply device 100 is provided to be spaced apart from the substrate processing apparatus 200, a temperature of the processing liquid can be appropriately brought close to a changed setting value. Thus, the processing liquid having an appropriately regulated temperature can be supplied to the substrate processing apparatus 200.

Further, the sum of the volume of the supply pipe 20 and the volume of the circulation pipe 30 is larger than the volume of the storage 110. With this configuration, even in a case in which the volume of the supply pipe 20 and the circulation pipe 30 is large since the processing liquid supply device 100 is provided to be spaced apart from the substrate processing apparatus 200, the processing liquid having an appropriately regulated temperature can be supplied to the substrate processing apparatus 200.

Based on the volume of the entire circulation path 101 including the volume of the supply pipe 20 and the volume of the circulation pipe 30, the amount calculator 163 of the control device 160 calculates a replacement amount of the processing liquid for making a temperature of the processing liquid reach a changed setting value. The replacer 164 of the control device 160 replaces the processing liquid having the replacement amount by executing the discharge process of discharging the processing liquid using the liquid drain 50 and the replenishment process of replenishing the storage 110 with the processing liquid by using the replenisher 60. In this case, the processing liquid having a regulated temperature can be supplied to the substrate processing apparatus 200 with simple control.

Specifically, in a case in which a changed temperature setting value is lower than a temperature of the processing liquid in the entire circulation path 101, the replacer 164 sequentially executes the discharge process of discharging the processing liquid having a replacement amount and the replenishment process of replenishing the storage 110 with the processing liquid having the replacement amount. In this case, the processing liquid having a regulated temperature can be supplied to the substrate processing apparatus 200 with more simple control. Further, the memory device 150 stores the volume of the entire circulation path 101. The amount calculator 163 calculates a replacement amount based on the volume of the entire circulation path 101 stored in the memory device 150. In this case, the replacement amount can be easily calculated.

Further, as described above, since the volume of the supply pipe 20 and the circulation pipe 30 is sufficiently large, the processing liquid having a relatively large amount flows through the supply pipe 20 and the circulation pipe 30. Even in this case, in the present embodiment, since the upstream end portion of the liquid drain pipe 51 is connected to the vicinity of the downstream end portion of the circulation pipe 30, the processing liquid remaining in the supply pipe 20 and the circulation pipe 30 can be efficiently discharged to the liquid drain device in the discharge process.

### 2. Second Embodiment

### (1) Processing Liquid Supply Process

Differences of a processing liquid supply device 100 according to a second embodiment from the processing liquid supply device 100 according to the first embodiment will be described below. In the first embodiment, the discharge process and the replenishment process are sequentially executed, once for each process. Further, in the discharge process, a processing liquid having a replacement amount is discharged. In the replenishment process, the storage is replenished with the processing liquid having the replacement amount. Thus, the processing liquid having the replacement amount is replaced.

In contrast, in the present embodiment, a discharge process and a replenishment process are alternately and repeatedly executed. Further, in each discharge process, a processing liquid having a predetermined amount smaller than the volume of a storage 110 (hereinafter referred to as a change amount) is discharged. In each replenishment process, the storage is replenished with the processing liquid having the change amount. The discharge process and the replenishment process are repeatedly and alternately executed until the processing liquid having a replacement amount is replaced.

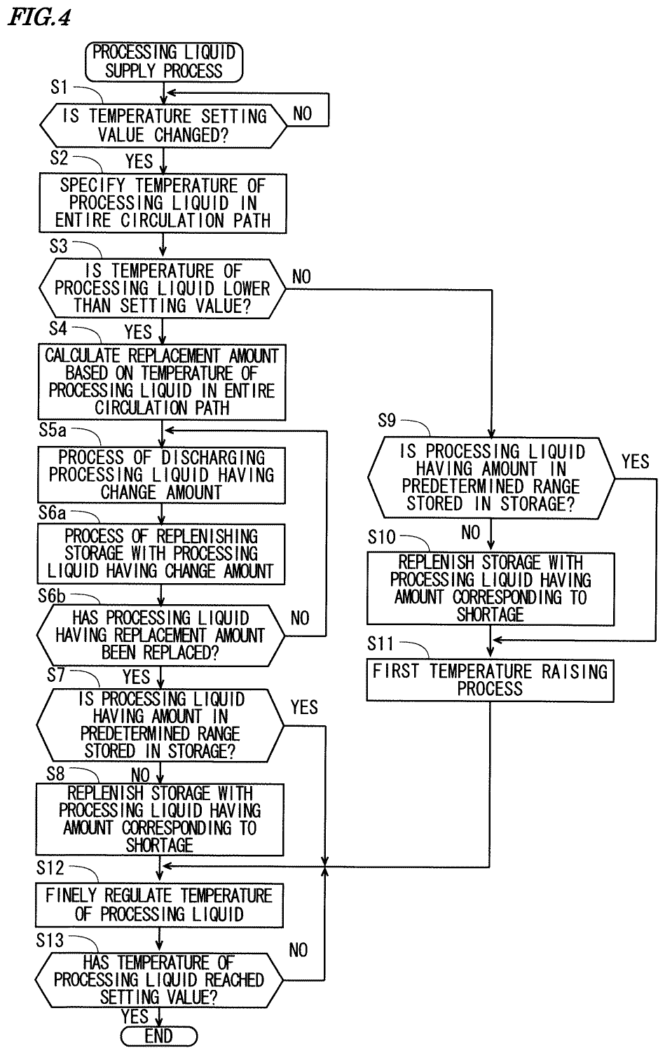

FIG. 4 is a flowchart showing the algorithm of a processing liquid supply process in the second embodiment. As shown in FIG. 4, in the present embodiment, the steps S5a and S6a are respectively executed instead of the steps S5 and S6 of FIG. 3. Further, after the step S6a, the step S6b is further executed.

Specifically, after the step S4, a replacer 164 executes the discharge process of discharging the processing liquid having the change amount from a circulation path 101 by opening an open-close valve 52 of a liquid drain 50 (step S5a). In the present example, the replacer 164 further opens an open-close valve 11 in the discharge process. After the process of discharging the processing liquid having the change amount ends, the replacer 164 closes open-close valves 11, 52. Next, the replacer 164 opens an open-close valve 61F of a replenisher 60 to execute the replenishment process of replenishing a storage 110 with the processing liquid having the change amount (step S6a). After the process of replenishing the storage 110 with the processing liquid having the change amount ends, the replacer 164 closes the open-close valve 61F.

Subsequently, the replacer 164 determines whether the processing liquid having the replacement amount calculated in the step S4 has been replaced (step S6b). In a case in which it is determined that the processing liquid having the replacement amount has not been replaced, the process returns to the step S5a. The steps S5a, S6a and S6b are repeated until it is determined that the processing liquid having the replacement amount has been replaced. In a case in which it is determined in the step S6b that the processing liquid having the replacement amount has been replaced, the process proceeds to the step S7. At this time, a determiner 162 may confirm, based on temperatures detected by temperature sensors 22, 32, 118, that the temperature of the processing liquid in the entire circulation path 101 has reached a target temperature.

### (2) Effects

In the processing liquid supply device 100 according to the present embodiment, in a case in which a changed temperature setting value is lower than a temperature of the processing liquid in the entire circulation path 101, the replacer 164 repeatedly executes the discharge process of discharging the processing liquid having the change amount smaller than the volume of the storage 110 and the replenishment process of replenishing the storage 110 with the processing liquid having the change amount, thereby replacing the processing liquid having a replacement amount. In this case, since the processing liquid having a certain amount or more always remains in the storage 110, a pump 120 does not run without the processing liquid. Therefore, it is not necessary to provide the pump 120 capable of working without the processing liquid. This increases a degree of freedom in regard to the configuration of the processing liquid supply device 100.

### 3. Third Embodiment

### (1) Processing Liquid Supply Process

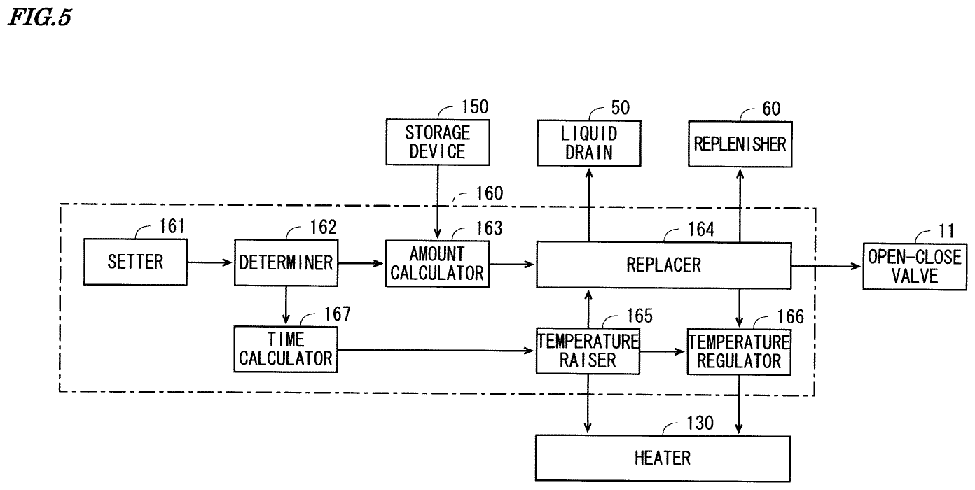

Differences of a processing liquid supply device 100 according to a third embodiment from the processing liquid supply device 100 according to the second embodiment will be described below. FIG. 5 is a diagram showing the configuration of a control device 160 in the third embodiment. As shown in FIG. 5, the control device 160 further includes a time calculator 167 as a function.

In the second embodiment, an amount calculator 163 calculates a replacement amount based on the volume of the entire circulation path 101 stored in the memory device 150 and a temperature of the processing liquid in the entire circulation path 101 specified by the determiner 162. In contrast, in the present embodiment, an amount calculator 163 calculates a replacement amount based on the volume of an entire circulation path 101 stored in a memory device 150 and a temperature detected by a temperature sensor 118. That is, in the present embodiment, the replacement amount is calculated based on the temperature of the processing liquid stored in the storage 110. Temperatures detected by temperature sensors 22, 32 do not have to be used in the calculation of a replacement amount.

Further, in a case in which a changed temperature setting value is higher than a temperature of the processing liquid in the entire circulation path 101, a temperature raiser 165 is configured to selectively execute the above-mentioned first temperature raising process and a second temperature raising process. The second temperature raising process is a process of controlling the heater 140 to bringing a temperature of the processing liquid close to a changed setting value while replacing the processing liquid using the replacer 164. The time calculator 167 calculates a first period of time required to make the temperature of the processing liquid reach a changed setting value in the first temperature raising process and a second period of time required to make the temperature of the processing liquid reach the changed setting value in the second temperature raising process. The temperature raiser 165 executes the first temperature raising process in a case in which the first period of time is equal to or smaller than the second period of time, and executes the second temperature raising process in a case in which the first period of time is larger than the second period of time.

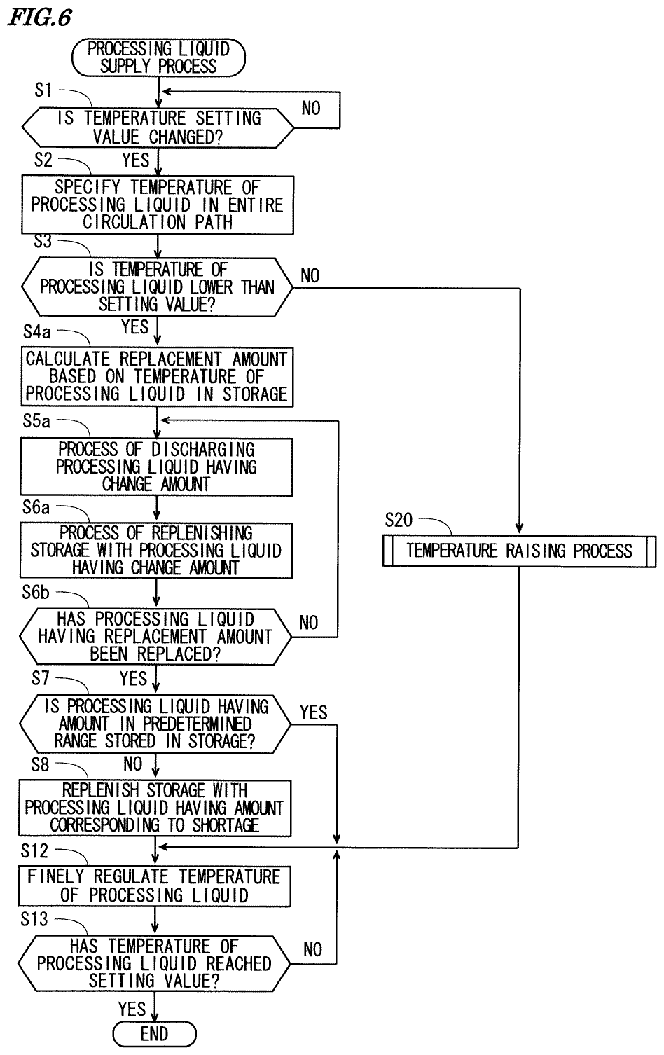

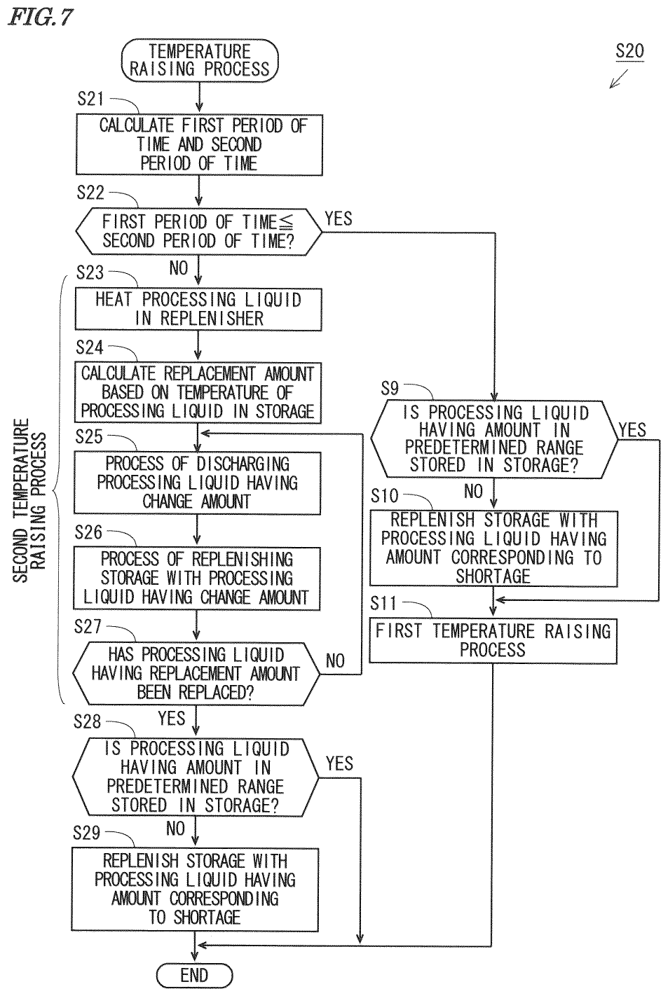

FIG. 6 and FIG. 7 are flowcharts showing the algorithm of a processing liquid supply process in the third embodiment. As shown in FIG. 6, in the present embodiment, the step S4a is executed instead of the step S4 of FIG. 4. Further, in a case in which it is determined in the step S3 that a temperature setting value is higher than a temperature of the processing liquid in the entire circulation path 101, a temperature raising process (step S20) of FIG. 7 is executed.

Specifically, in a case in which it is determined that the temperature setting value is lower than the temperature of the processing liquid in the entire circulation path 101, the amount calculator 163 calculates a replacement amount of the processing liquid for making the temperature of the processing liquid in the storage 110 reach a target temperature, based on the volume of the entire circulation path 101, an amount of the processing liquid in the storage 110 based on the detection results of liquid level sensors 116, 117, and a temperature of the processing liquid in the storage 110 detected by a temperature sensor 118 (step S4a). Thereafter, the process proceeds to the step S5a.

Thereafter, the steps S5a, S6a and S6b are repeated until it is determined that the processing liquid having the replacement amount calculated in the step S4a has been replaced. Thus, the temperature of the processing liquid in the storage 110 reaches the target temperature, and the process proceeds to the step S7. At this time, based on a temperature detected by the temperature sensor 118, the determiner 162 may confirm that the temperature of the processing liquid in the storage 110 has reached the target temperature.

On the other hand, in a case in which it is determined in the step S3 that the temperature setting value is higher than the temperature of the processing liquid in the entire circulation path 101, the temperature raising process is executed (step S20). In the temperature raising process, the temperature raiser 165 first calculates a first period of time and a second period of time (step S21). The first period of time is calculated based on the difference between a temperature setting value and a temperature of the processing liquid in the storage 110 (hereinafter referred to as a setting temperature difference), and a volume of the entire circulation path 101, for example. The second period of time is calculated based on a setting temperature difference, a volume of the entire circulation path 101, an amount of the processing liquid with which the storage 110 is replenished by the replenisher 60, and a temperature of the processing liquid with which the storage 110 is replenished by the replenisher 60, for example.

Next, the temperature raiser 165 determines whether the first period of time calculated in the step S21 is equal to or smaller than the second period of time calculated in the step S21 (step S22). In a case in which it is determined that the first period of time is equal to or smaller than the second period of time, the steps S9 to S11 similar to those in the second embodiment are executed. Thus, the temperature raising process ends. Thereafter, the process proceeds to the step S12 of the processing liquid supply process.

In a case in which it is determined in the step S22 that the first period of time is longer than the second period of time, the second temperature raising process in the following steps S23 to S27 is executed. Specifically, the temperature raiser 165 first drives the heater 140 to heat the processing liquid supplied from a pure water supplier 62B (step S23). Thus, the processing liquid heated to a predetermined temperature can be supplied from the replenisher 60. The step S23 continues until the second temperature raising process ends.

Further, similarly to the step S4a, the amount calculator 163 calculates a replacement amount of the processing liquid for making the temperature of the processing liquid in the storage 110 reach a target temperature based on a volume of the entire circulation path 101, an amount of the processing liquid in the storage 110 based on detection results of the liquid level sensors 116, 117, and a temperature of the processing liquid in the storage 110 detected by the temperature sensor 118 (step S24). Either one of the steps S23 and S24 may be executed first, or the steps S23 and S24 may be executed at the same time.

Next, the replacer 164 executes a discharge process of discharging the processing liquid having a change amount from the circulation path 101, similarly to the step S5a (step S25). In the present example, the replacer 164 further opens an open-close valve 11 in the discharge process. After the process of discharging the processing liquid having the change amount ends, the replacer 164 closes open-close valves 11, 52. Subsequently, the replacer 164 opens an open-close valve 62F of the replenisher 60 to execute a replenishment process of replenishing the storage 110 with the processing liquid having the change amount (step S26). In this case, the storage 110 is replenished with the processing liquid supplied by the pure water supplier 62B and heated by the heater 140.

In the replenishment process of the step S26, the storage 110 may be replenished with the processing liquid (hot water) supplied by a hot water supplier 63B instead of the processing liquid supplied by the pure water supplier 62B or in addition to the processing liquid supplied by the pure water supplier 62B. In this case, an open-close valve 63F is opened instead of the open-close valve 62F or in addition to the open-close valve 62F. Here, in a case in which the processing liquid supplied by the pure water supplier 62B is not used in the replenishment process, the step S23 does not have to be executed. After the process of replenishing the storage 110 with the processing liquid having the change amount, the replacer 164 closes the open-close valves 62F, 63F.

Thereafter, similarly to the step S6b, the replacer 164 determines whether the processing liquid having the replacement amount calculated in the step S24 has been replaced (step S27). In a case in which it is determined that the processing liquid having the replacement amount has not been replaced, the process returns to the step S25. The steps S25 to S27 are repeated until it is determined that the processing liquid having the replacement amount has been replaced. In a case in which it is determined in the step S27 that the processing liquid having the replacement amount has been replaced, the second temperature raising process ends, and the process proceeds to the step S28. At this time, based on a temperature detected by the temperature sensor 118, the determiner 162 may confirm that the temperature of the processing liquid in the storage 110 has reached the target temperature.

Next, similarly to the step S7, the replacer 164 determines whether the processing liquid having an amount in a predetermined range is stored in the storage 110 (step S28). In a case in which it is determined that the processing liquid having an amount in the predetermined range is not stored in the storage 110, the replacer 164 replenishes the storage 110 with the processing liquid having an amount corresponding to the shortage by opening part or all of the open-close valves 61F to 63F (step S29). After the storage 110 is replenished with the processing liquid having an amount corresponding to the shortage, the open-close valves 61F to 63F are closed. Thus, the temperature raising process ends. Thereafter, the process proceeds to the step S12 of the processing liquid supply process. At this time, based on the detection results of flow-rate sensors 21, 31 and the liquid level sensors 116, 117, the replacer 164 may confirm that the circulation path 101 is filled with the processing liquid.

### (2) Effects

In the processing liquid supply device 100 according to the present embodiment, the amount calculator 163 calculates a replacement amount based on a temperature of the processing liquid stored in the storage 110. In this case, because the replacement amount is relatively small, even in a case in which the discharge process and the replenishment process are repeated, the temperature of the processing liquid can be brought close to a changed setting value in a short period of time.

Further, the heater 130 is configured to be capable of heating the processing liquid flowing through the circulation pipe 30. The heater 140 is configured to be capable of heating the processing liquid with which the storage 110 is replenished by the replenisher 60. In a case in which a changed temperature setting value is higher than a temperature of the processing liquid in the entire circulation path 101, the temperature raiser 165 of the control device 160 selectively executes the first temperature raising process and the second temperature raising process. The first temperature raising process is a process of controlling the heater 130 to bring the temperature of the processing liquid close to the changed setting value without replacement of the processing liquid by the replacer 164. The second temperature raising process is a process of controlling the heater 140 to bring the temperature of the processing liquid close to the changed setting value while replacing the processing liquid using the replacer 164. With this configuration, in a case in which the changed temperature setting value is higher than the temperature of the processing liquid in the entire circulation path 101, it is possible to execute a process in which energy consumption and processing liquid consumption are more sufficiently reduced.

Here, the time calculator 167 of the control device 160 calculates the first period of time required to make the temperature of the processing liquid reach the changed setting value in the first temperature raising process and a second period of time required to make the temperature of the processing liquid reach the changed setting value in the second temperature raising process. The temperature raiser 165 may execute the first temperature raising process in a case in which the first period of time is equal to or smaller than the second period of time, and may execute the second temperature raising process in a case in which the first period of time is longer than the second period of time. With this configuration, in a case in which the changed temperature setting value is higher than the temperature of the processing liquid in the entire circulation path 101, the temperature of the processing liquid can be brought close to the changed setting value in a short period of time.

### 4. Other Embodiments

(1) While the sum of the volume of the supply pipe 20 and the volume of the circulation pipe 30 is larger than the volume of the storage 110 in the above-mentioned embodiment, the embodiment is not limited to this. The sum of the volume of the supply pipe 20 and the volume of the circulation pipe 30 may be equal to or smaller than the volume of the storage 110.
(2) While the volume of the entire circulation path 101 is stored in the memory device 150 in the above-mentioned embodiment, the embodiment is not limited to this. As long as the amount calculator 163 can acquire a volume of the entire circulation path 101, the volume of the entire circulation path 101 does not have to be stored in the memory device 150.
(3) While the replenisher 60 includes the three replenishment units 61 to 63 in the above-mentioned embodiment, the embodiment is not limited to this. The replenisher 60 is only required to include any one of the three replenishment units 61 to 63. Therefore, the replenisher 60 does not have to include one or two replenishment units among the three replenishment units 61 to 63.
(4) While the replacer 164 sequentially executes the discharge process and the replenishment process in the first embodiment, the embodiment is not limited to this. The replacer 164 may execute the discharge process and the replenishment process at the same time.
(5) While the temperature raiser 165 is configured to be capable of executing only the first temperature raising process in the first embodiment or the second embodiment, the embodiment is not limited to this. Similarly to the third embodiment, the temperature raiser 165 may be configured to be capable of selectively executing the first temperature raising process and the second temperature raising process. In this case, in the second temperature raising process, the amount calculator 163 may calculate a replacement amount of the processing liquid for making a temperature of the processing liquid in the entire circulation path 101 reach a target temperature, based on temperatures detected by the temperature sensors 22, 32, 118.

On the other hand, in the third embodiment, the temperature raiser 165 is configured to be capable of selectively executing the first temperature raising process and the second temperature raising process. However, the embodiment is not limited to this. Similarly to the first embodiment and the second embodiment, the temperature raiser 165 may be configured to be capable of executing only the first temperature raising process.

Here, in a case in which the temperature raiser 165 is configured to be capable of executing the second temperature raising process, the temperature raiser 165 executes the first temperature raising process when a first period of time is equal to or smaller than a second period of time, and the temperature raiser 165 executes the second temperature raising process when the first period of time is longer than the second period of time. However, the embodiment is not limited to this. In a case in which a setting temperature difference is relatively small, the temperature raiser 165 may execute the first temperature raising process. In a case in which a setting temperature difference is relatively large, the temperature raiser 165 may execute the second temperature raising process. For example, in a case in which a setting temperature difference is equal to or smaller than a predetermined threshold value, the temperature raiser 165 may execute the first temperature raising process. In a case in which a setting temperature difference is larger than the threshold value, the temperature raiser 165 may execute the second temperature raising process. In this case, the control device 160 does not have to include the time calculator 167.

### 5. Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained. As each of various elements recited in the claims, various other elements having configurations or functions described in the claims can be also used.

In the above-mentioned embodiment, the substrate processing apparatus 200 is an example of a substrate processing apparatus, the processing liquid supply device 100 is an example of a processing liquid supply device, the outlet 112 is an example of an outlet, the inlet 113 is an example of an inlet, and the storage 110 is an example of a storage. The supply pipe 20 is an example of a supply pipe, the circulation pipe 30 is an example of a circulation pipe, the pump 120 is an example of a pump, the liquid drain 50 is an example of a liquid drain, the replenisher 60 is an example of a replenisher, the control device 160 is an example of a controller, and the amount calculator 163 is an example of an amount calculator. The replacer 164 is an example of a replacer, the memory device 150 is an example of a memory, the heater 130 is an example of a first heater, the heater 140 is an example of a second heater, the temperature raiser 165 is an example of a temperature raiser, and the time calculator 167 is an example of a time calculator.

### 6. Overview of Embodiments

(Item 1) A processing liquid supply device according to item 1 that supplies a processing liquid to a substrate processing apparatus, includes a storage that stores the processing liquid and has an outlet through which the stored processing liquid is sent and an inlet through which the processing is fed, a supply pipe that connects the outlet of the storage to the substrate processing apparatus, a circulation pipe that connects the substrate processing apparatus to the inlet of the storage, a pump that sends out the processing liquid stored in the storage from the outlet to the supply pipe, a liquid drain that is provided in the circulation pipe and configured to be capable of discharging the processing liquid flowing through the circulation pipe, a replenisher configured to be capable of replenishing the storage with the processing liquid, and a controller that, in a case in which a temperature setting value is changed, brings a temperature of the processing liquid close to a changed setting value by controlling the liquid drain and the replenisher based on a temperature of the processing liquid in an entire circulation path that includes a temperature of the processing liquid flowing through the circulation pipe.

In this processing liquid supply device, the liquid drain and the replenisher operate based on a temperature of the processing liquid in the entire circulation path, with the temperature including a temperature of the processing liquid flowing through the circulation path. Therefore, even in a case in which the volume of the circulation path is large because the processing liquid supply device is provided to be spaced apart from the substrate processing apparatus, it is possible to bring the temperature of the processing liquid close to the changed setting value. Thus, it is possible to supply the processing liquid having an appropriately regulated temperature to the substrate processing apparatus.
(Item 2) The processing liquid supply device according to item 1, wherein a sum of a volume of the supply pipe and a volume of the circulation pipe may be larger than a volume of the storage.

With this configuration, even in a case in which the volume of the supply pipe and the circulation pipe is sufficiently large because the processing liquid supply device is provided to be spaced apart from the substrate processing apparatus, it is possible to supply the processing liquid having an appropriately regulated temperature to the substrate processing apparatus.
(Item 3) The processing liquid supply device according to item 1, wherein the controller may include an amount calculator that calculates a replacement amount of the processing liquid for making a temperature of the processing liquid reach a changed setting value based on a volume of the entire circulation path that includes a volume of the supply pipe and a volume of the circulation pipe, and a replacer that replaces the processing liquid having the replacement amount by executing a discharge process of discharging the processing liquid using the liquid drain and a replenishment process of replenishing the storage with the processing liquid using the replenisher.

In this case, it is possible to supply the processing liquid having a regulated temperature to the substrate processing apparatus with simple control.
(Item 4) The processing liquid supply device according to item 3, may further include a memory that stores the volume of the entire circulation path, wherein the amount calculator may calculate the replacement amount based on the volume of the entire circulation path stored in the memory.

In this case, it is possible to easily calculate the replacement amount.
(Item 5) The processing liquid supply device according to item 3 or 4, wherein the replacer, in a case in which the changed setting value of temperature is lower than the temperature of the processing liquid in the entire circulation path, may sequentially execute the discharge process of discharging the processing liquid having the replacement amount and the replenishment process of replenishing the storage with the processing liquid having the replacement amount.

In this case, it is possible to supply the processing liquid having a regulated temperature to the substrate processing apparatus with more simple control.
(Item 6) The processing liquid supply device according to item 3 or 4, wherein the replacer, in a case in which the changed setting value of temperature is lower than the temperature of the processing liquid in the entire circulation path, may replace the processing liquid having the replacement amount by alternately and repeatedly executing the discharge process of discharging the processing liquid having a change amount smaller than a volume of the storage and the replenishment process of replenishing the storage with the processing liquid having the change amount.

In this case, since the processing liquid having a certain amount or more always remains in the storage, a pump does not work without the processing liquid. Therefore, it is not necessary to provide a pump capable of working without the processing liquid. This improves a degree of freedom in regard to the configuration of the processing liquid supply device.
(Item 7) The processing liquid supply device according to item 6, wherein the amount calculator may calculate the replacement amount based on a temperature of the processing liquid stored in the storage.

In this case, because the replacement amount is relatively small, even in a case in which the discharge process and the replenishment process are repeated, it is possible to bring the temperature of the processing liquid close to a changed setting value in a short period of time.
(Item 8) The processing liquid supply device according to any one of items 3 to 7, may further include a first heater configured to be capable of heating the processing liquid flowing through the circulation pipe, and a second heater configured to be capable of heating the processing liquid with which the storage is replenished by the replenisher, wherein the controller may include a temperature raiser that, in a case in which the changed setting value of temperature is higher than the temperature of the processing liquid in the entire circulation path, selectively executes a first temperature raising process of controlling the first heater to bring the temperature of the processing liquid close to the changed setting value without replacement of the processing liquid by the replacer, and a second temperature raising process of controlling the second heater while replacing the processing liquid using the replacer to bring the temperature of the processing liquid close to the changed setting value.

With this configuration, in a case in which the changed temperature setting value is higher than the temperature of the processing liquid in the entire circulation path, it is possible to execute a process in which energy consumption and processing liquid consumption are more sufficiently reduced.
(Item 9) The processing liquid supply device according to item 8, wherein the controller may further include a time calculator that calculates a first period of time required to make the temperature of the processing liquid reach the changed setting value in the first temperature raising process, and a second period of time required to make the temperature of the processing liquid reach the changed setting value in the second temperature raising process, and the temperature raiser may execute the first temperature raising process in a case in which the first period of time is equal to or smaller than the second period of time, and the second temperature raising process in a case in which the first period of time is longer than the second period of time.

With this configuration, in a case in which the changed temperature setting value is higher than the temperature of the processing liquid in the entire circulation path, it is possible to bring the temperature of the processing liquid close to the changed setting value in a short period of time.
(Item 10) A processing liquid supply method according to item 10 of supplying a processing liquid having a setting temperature to a substrate processing apparatus using a processing liquid supply device, includes sending out the processing liquid stored in a storage using a pump to a supply pipe that connects an outlet of the storage to the substrate processing apparatus, feeding the processing liquid into the storage using a circulation pipe that connects the substrate processing apparatus to an inlet of the storage, and in a case in which a temperature setting value is changed, based on a temperature of the processing liquid in an entire circulation path that includes a temperature of the processing liquid flowing through the circulation pipe, bringing the temperature of the processing liquid close to a changed setting value by discharging the processing liquid flowing through the circulation pipe using a liquid drain provided in the circulation pipe and replenishing the storage with the processing liquid.

With this processing liquid supply method, the liquid drain and the replenisher operate based on a temperature of the processing liquid in the entire circulation path, with the temperature including a temperature of the processing liquid flowing through the circulation path. Therefore, even in a case in which the volume of the circulation path is large because the processing liquid supply device is provided to be spaced apart from the substrate processing apparatus, it is possible to bring the temperature of the processing liquid close to the changed setting value. Thus, it is possible to supply the processing liquid having an appropriately regulated temperature to the substrate processing apparatus.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

I/We claim:

1. A processing liquid supply device that supplies a processing liquid to a substrate processing apparatus, comprising:
a storage that stores the processing liquid and has an outlet through which the stored processing liquid is sent and an inlet through which the processing is fed;
a supply pipe that connects the outlet of the storage to the substrate processing apparatus;
a circulation pipe that connects the substrate processing apparatus to the inlet of the storage;
a pump that sends out the processing liquid stored in the storage from the outlet to the supply pipe;
a liquid drain that is provided in the circulation pipe and configured to be capable of discharging the processing liquid flowing through the circulation pipe;
a replenisher configured to be capable of replenishing the storage with the processing liquid; and
a controller that, in a case in which a temperature setting value is changed, brings a temperature of the processing liquid close to a changed setting value by controlling the liquid drain and the replenisher based on a temperature of the processing liquid in an entire circulation path that includes a temperature of the processing liquid flowing through the circulation pipe.

2. The processing liquid supply device according to claim 1, wherein
a sum of a volume of the supply pipe and a volume of the circulation pipe is larger than a volume of the storage.

3. The processing liquid supply device according to claim 1, wherein
the controller includes
an amount calculator that calculates a replacement amount of the processing liquid for making a temperature of the processing liquid reach a changed setting value based on a volume of the entire circulation path that includes a volume of the supply pipe and a volume of the circulation pipe, and
a replacer that replaces the processing liquid having the replacement amount by executing a discharge process of discharging the processing liquid using the liquid drain and a replenishment process of replenishing the storage with the processing liquid using the replenisher.

4. The processing liquid supply device according to claim 3, further comprising a memory that stores the volume of the entire circulation path, wherein
the amount calculator calculates the replacement amount based on the volume of the entire circulation path stored in the memory.

5. The processing liquid supply device according to claim 3, wherein
the replacer, in a case in which the changed setting value of temperature is lower than the temperature of the processing liquid in the entire circulation path, sequentially executes the discharge process of discharging the processing liquid having the replacement amount and the replenishment process of replenishing the storage with the processing liquid having the replacement amount.

6. The processing liquid supply device according to claim 3, wherein
the replacer, in a case in which the changed setting value of temperature is lower than the temperature of the processing liquid in the entire circulation path, replaces the processing liquid having the replacement amount by alternately and repeatedly executing the discharge process of discharging the processing liquid having a change amount smaller than a volume of the storage and the replenishment process of replenishing the storage with the processing liquid having the change amount.

7. The processing liquid supply device according to claim 6, wherein
the amount calculator calculates the replacement amount based on a temperature of the processing liquid stored in the storage.

8. The processing liquid supply device according to claim 3, further comprising:
a first heater configured to be capable of heating the processing liquid flowing through the circulation pipe; and
a second heater configured to be capable of heating the processing liquid with which the storage is replenished by the replenisher, wherein
the controller includes a temperature raiser that, in a case in which the changed setting value of temperature is higher than the temperature of the processing liquid in the entire circulation path, selectively executes a first temperature raising process of controlling the first heater to bring the temperature of the processing liquid close to the changed setting value without replacement of the processing liquid by the replacer, and a second temperature raising process of controlling the second heater while replacing the processing liquid using the replacer to bring the temperature of the processing liquid close to the changed setting value.

9. The processing liquid supply device according to claim 8, wherein
the controller further includes a time calculator that calculates a first period of time required to make the temperature of the processing liquid reach the changed setting value in the first temperature raising process, and a second period of time required to make the temperature of the processing liquid reach the changed setting value in the second temperature raising process, and
the temperature raiser executes the first temperature raising process in a case in which the first period of time is equal to or smaller than the second period of time, and the second temperature raising process in a case in which the first period of time is longer than the second period of time.

10. A processing liquid supply method of supplying a processing liquid having a setting temperature to a substrate processing apparatus using a processing liquid supply device, including:
sending out the processing liquid stored in a storage using a pump to a supply pipe that connects an outlet of the storage to the substrate processing apparatus;
feeding the processing liquid into the storage using a circulation pipe that connects the substrate processing apparatus to an inlet of the storage; and
in a case in which a temperature setting value is changed, based on a temperature of the processing liquid in an entire circulation path that includes a temperature of the processing liquid flowing through the circulation pipe, bringing the temperature of the processing liquid close to a changed setting value by discharging the processing liquid flowing through the circulation pipe using a liquid drain provided in the circulation pipe and replenishing the storage with the processing liquid.
